(19) United States
(12) Patent Application Publication
(10) Pub. No.: US 2026/0123418 A1
(43) Pub. Date: Apr. 30, 2026

(54) SEMICONDUCTOR DEVICE

(71) Applicant: FUJI ELECTRIC CO., LTD., Kawasaki-shi (JP)

(72) Inventors: Motohito HORI, Matsumoto-city (JP); Mai SAITO, Matsumoto-city (JP); Akira HIRAO, Matsumoto-city (JP)

(73) Assignee: FUJI ELECTRIC CO., LTD., Kawasaki-shi (JP)

(21) Appl. No.: 19/433,627

(22) Filed: Dec. 26, 2025

Related U.S. Application Data
(63) Continuation of application No. PCT/JP2024/041777, filed on Nov. 26, 2024.

(30) Foreign Application Priority Data
Jan. 17, 2024 (JP) 2024-005109

(51) Int. Cl. H10W 40/25; H10D 80/20; H10W 72/00; H10W 74/10; H10W 90/00; H10W 90/10

(52) U.S. Cl. CPC H10W 40/257; H10D 80/251; H10W 40/255; H10W 72/877; H10W 74/114; H10W 90/10; H10W 90/724; H10W 90/734

(57) ABSTRACT

A semiconductor device, including: a heat dissipation plate having a heat dissipation surface; a cooling module having a cooling surface, the cooling module being disposed so that the cooling surface faces the heat dissipation surface of the heat dissipation plate; and a bonding member provided between the heat dissipation surface and the cooling surface. The bonding member includes: a thermally conductive part that bonds the heat dissipation surface and the cooling surface, and an electrically conductive part that electrically connects the heat dissipation surface and the cooling surface.

### CROSS-REFERENCE TO RELATED APPLICATION

This application is a continuation application of International Application PCT/JP2024/041777 filed on Nov. 26, 2024, which designated the U.S., which claims priority to Japanese Patent Application No. 2024-005109, filed on Jan. 17, 2024, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a multilayer substrate, in which a metal plate, an insulating layer, and a conductive plate are laminated in that order from below, and semiconductor chips disposed on the conductive plate. The semiconductor device further includes a heat dissipation plate on which the multilayer substrate is disposed, a case that is disposed on the heat dissipation plate and houses the multilayer substrate and the semiconductor chips, and screws that fix the case and the heat dissipation plate. When doing so, the screws and the metal plate are connected by a connecting member that is electrically conductive (see, for example, Japanese Laid-open Patent Publication No. 2020-87966, Japanese Laid-open Patent Publication No. 2022-48552, and Japanese Laid-open Patent Publication No. 2022-18033).

In another semiconductor device, a conductive plate on the rear surface of a laminated substrate is disposed on a cooler via a thermal compound containing particles with a high dielectric constant, here a relative dielectric constant of 10 or more. The components on the cooler are encapsulated with an encapsulating member (see, for example, Japanese Laid-open Patent Publication No. 2019-41013).

In another semiconductor device, a rear surface electrode, which is bonded to the rear surface of an insulating substrate by a brazing material, is disposed via solder on a metal base. A solder resist is applied around the solder. When doing so, the distance between the end of the brazing material and the side surface of the insulating substrate is smaller than the distance between the solder-side end of the solder resist and the side surface of the insulating substrate (see, for example, Japanese Laid-open Patent Publication No. 2019-80014).

### SUMMARY OF THE INVENTION

According to an aspect, there is provided a semiconductor device, including: a heat dissipation plate having a heat dissipation surface; a cooling module having a cooling surface, the cooling module being disposed so that the cooling surface faces the heat dissipation surface of the heat dissipation plate; and a bonding member provided between the heat dissipation surface and the cooling surface; wherein the bonding member includes: a thermally conductive part that bonds the heat dissipation surface and the cooling surface, and an electrically conductive part that directly connects the heat dissipation plate to the cooling surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a side sectional view of a semiconductor device according to a first embodiment;

FIG. 2 is a plan view of a cooling surface of the semiconductor device according to the first embodiment;

FIG. 3 is a flowchart depicting a method of manufacturing the semiconductor device according to the first embodiment;

FIG. 4 is a (first) diagram useful in explaining a semiconductor module assembling process according to the first embodiment;

FIG. 5 is a (second) diagram useful in explaining the semiconductor module assembling process according to the first embodiment;

FIG. 6 is a side sectional view of the semiconductor module according to the first embodiment;

FIG. 7 is a rear view of the semiconductor module according to the first embodiment;

FIG. 8 is a (first) diagram useful in explaining an application process in the first embodiment;

FIG. 9 is a (second) diagram useful in explaining the application process in the first embodiment;

FIG. 10 is a (third) diagram useful in explaining the application process in the first embodiment;

FIG. 11 is a (fourth) diagram useful in explaining the application process in the first embodiment;

FIG. 12 is a side sectional view of a semiconductor device according to a comparative example;

FIG. 13 is a plan view of a cooling surface of the semiconductor device according to the comparative example;

FIG. 14 is a side sectional view of a semiconductor device according to a second embodiment;

FIG. 15 is a plan view of a cooling surface of the semiconductor device according to the second embodiment;

FIG. 16 is a (first) diagram useful in explaining an application process in a third embodiment;

FIG. 17 is a (second) diagram useful in explaining the application process in the third embodiment;

FIG. 18 is a side sectional view of a semiconductor device according to the third embodiment;

FIG. 19 is a plan view of a cooling surface of a semiconductor device according to a fourth embodiment;

FIG. 20 is a side sectional view of a semiconductor device according to a fifth embodiment;

FIG. 21 is a rear view of the semiconductor module according to the fifth embodiment;

FIG. 22 is a side sectional view of a semiconductor device according to a sixth embodiment;

FIG. 23 is a rear view of the semiconductor module according to the sixth embodiment;

FIG. 24 is a side view of the semiconductor device according to the sixth embodiment;

FIG. 25 is a (first) diagram useful in explaining an application process in the sixth embodiment;

FIG. 26 is a (second) diagram useful in explaining the application process in the sixth embodiment; and

FIG. 27 is a diagram useful in explaining an attachment process according to the sixth embodiment.

### DETAILED DESCRIPTION OF THE INVENTION

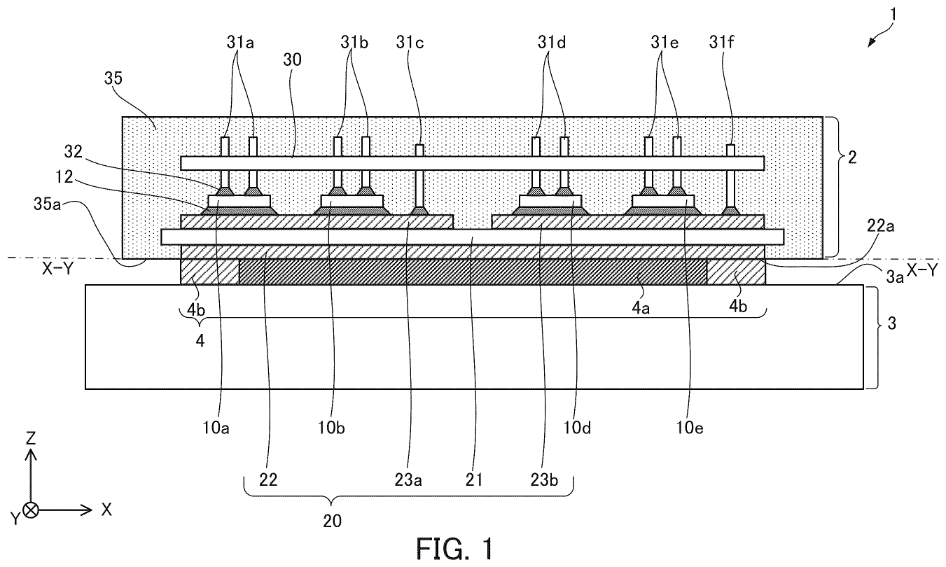

Several embodiments will now be described with reference to the accompanying drawings. In the following description, the expressions “front surface” and “upper surface” refer to an X-Y plane that faces upward (in the +Z direction) for the semiconductor device 1 appearing in the drawings. In the same way, the expression “upper” indicates an upward direction (+Z direction) for the semiconductor device in FIG. 1. The expressions “rear surface” and “lower surface” refer to an X-Y plane that faces downward (in the −Z direction) for the semiconductor device 1 in FIG. 1. In the same way, the expression “below” indicates a downward direction (−Z direction) for the semiconductor device 1 in FIG. 1. The same directions as described above are indicated as needed in all of the drawings. The expressions “higher” and “above” indicate positions toward the upper side (the +Z direction) for the semiconductor device 1 in FIG. 1. In the same way, the expressions “lower” and “below” indicate positions on the lower side (the −Z direction) for the semiconductor device 1 in FIG. 1. The expressions “front surface”, “upper surface”, “upper” and “rear surface”, “lower surface”, “lower” and “side surface” are merely convenient expressions for specifying relative positional relationships, and do not limit the technical scope of the present disclosure. As examples, “up” and “down” do not necessarily mean the vertical direction with respect to the ground. That is, the “up” and “down” directions are not limited to the direction of gravity. Also in the following description, the expression “main component” indicates a component that composes 80 vol % or more. Values that are “substantially the same” may be within a range of ±10%. Likewise, “perpendicular”, “orthogonal”, and “parallel” may be within a range of ±10°.

### First Embodiment

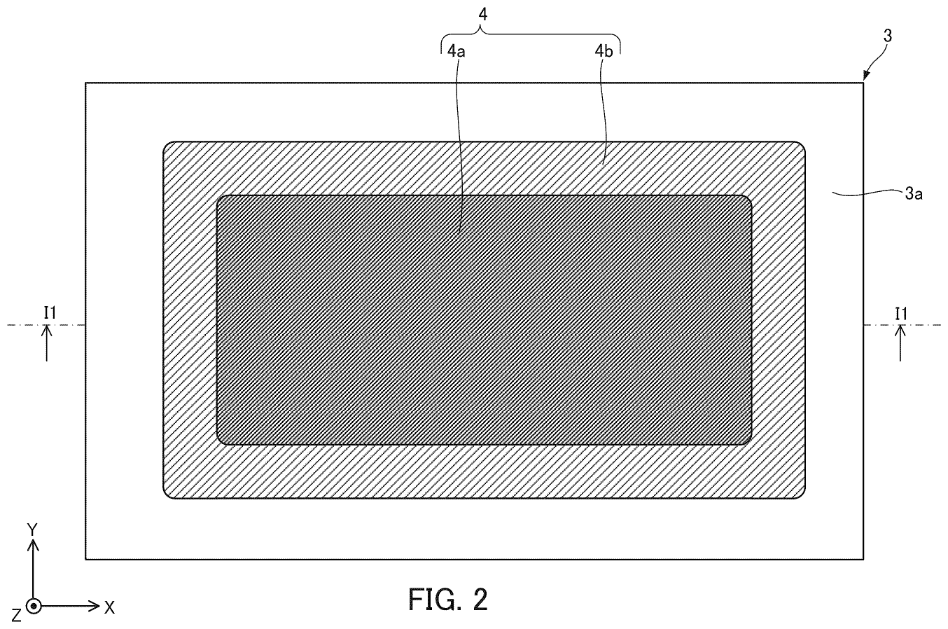

A semiconductor device 1 according to a first embodiment will now be described with reference to FIGS. 1 and 2. FIG. 1 is a side sectional view of a semiconductor device according to a first embodiment. FIG. 2 is a plan view of a cooling surface of the semiconductor device according to the first embodiment. Note that FIG. 2 is a cross-sectional view of the semiconductor device 1 in FIG. 1 taken along the X-Y plane indicated by a chain line. That is, FIG. 2 is a plan view of a cooling surface 3a on which a bonding member 4 of a cooling module 3 is provided. FIG. 1 is a cross-sectional view taken along a chain line I1-I1 in FIG. 2 when looking in the +Y direction.

The semiconductor device 1 includes a semiconductor module 2, the cooling module 3, and the bonding member 4 that fixes the semiconductor module 2 and the cooling module 3. Note that the semiconductor device 1 may also include other components as needed in addition to the components mentioned here.

The semiconductor module 2 includes semiconductor chips 10a, 10b, 10d, and 10e, an insulated circuit board 20, a printed circuit board 30, and an encapsulating member 35 that encapsulates these components. The semiconductor chips 10a, 10b, 10d, and 10e may be power metal-oxide-semiconductor field-effect transistors (power MOSFETs) that have silicon carbide as a main component. In these power MOSFETs, the body diode may function as a freewheeling diode (FWD). As one example, each of the semiconductor chips 10a, 10b, 10d, and 10e includes an input electrode (drain electrode) as a main electrode on the rear surface, and an output electrode (source electrode) as a main electrode and a control electrode (gate electrode) on the front surface. The control electrode may be provided at the center of one edge of the front surface of each of the semiconductor chips 10a, 10b, 10d, and 10e or at a position shifted from the center along the edge.

Alternatively, the semiconductor chips 10a, 10b, 10d, and 10e may include a switching element that has silicon as a main component. As one example, the switching elements are reverse-conducting insulated gate bipolar transistors (RC-IGBT). An RC-IGBT is a semiconductor element in which an IGBT and an FWD are configured in anti-parallel inside a single chip.

Each of the semiconductor chips 10a, 10b, 10d, and 10e includes an input electrode (collector electrode), which is a main electrode, on the rear surface, and an output electrode (emitter electrode), which is a main electrode, and a control electrode (gate electrode) on the front surface. As in the case of a power MOSFET, the control electrode may be provided at the center of one edge of the front surface of each of the semiconductor chips 10a, 10b, 10d, and 10e or at a position shifted from the center along the edge.

Alternatively, the semiconductor chips 10a, 10b, 10d, and 10e may be semiconductor chips that have silicon as a main component and form pairs of a switching element and a diode element. In more detail, the semiconductor chips 10a and 10d may be switching elements, and the semiconductor chips 10b and 10e may be diode elements. The switching elements are power MOSFETs or IGBTs, for example. As examples, a semiconductor chip that includes a switching element includes an input electrode (the drain electrode in the case of a power MOSFET and the collector electrode in the case of an IGBT) as a main electrode on the rear surface, and a gate electrode as a control electrode and an output electrode (the source electrode in the case of a power MOSFET and the emitter electrode in the case of an IGBT) as a main electrode on the front surface. As examples of diode elements, a Schottky barrier diode (SBD) or a P-intrinsic-N (PiN) diode is used as an FWD. A semiconductor chip including a diode element includes an output electrode (cathode electrode) as a main electrode on the rear surface and an input electrode (anode electrode) as a main electrode on the front surface.

The semiconductor chips 10a and 10b and the semiconductor chips 10d and 10e may be bonded by solder 12 respectively to conductive circuit patterns 23a and 23b (described later). The solder 12 is made of a solder component. The solder component includes lead-free solder containing a predetermined alloy as a main component. The predetermined alloy contains tin. Example alloys include at least one of tin-silver alloy, tin-silver-copper alloy, tin-zinc-bismuth alloy, tin-copper alloy, tin-silver-indium-bismuth alloy, and tin-antimony alloy. The solder component may also include additives. Example additives include nickel, germanium, cobalt, and silicon. Examples of the solder component include tin and at least one of silver, zinc, copper, bismuth, indium, and antimony. The solder component may further include at least one of nickel, germanium, cobalt, and silicon, for example. Sintered metal may be used instead of the solder 12. Examples of sintered material when bonding is achieved with a sintered metal include powder of silver, iron, copper, aluminum, titanium, nickel, tungsten, or molybdenum.

The insulated circuit board 20 includes an insulating plate 21, a heat dissipation plate 22, and the conductive circuit patterns 23a and 23b. The insulating plate 21 and the heat dissipation plate 22 are rectangular in shape in plan view. Corner portions of the insulating plate 21 and the heat dissipation plate 22 may be chamfered into rounded or beveled shapes. The size of the heat dissipation plate 22 is smaller than the size of the insulating plate 21 in plan view, and the heat dissipation plate 22 is formed inside the insulating plate 21.

An example of the insulating plate 21 includes a ceramics substrate. Such ceramics substrate is made of ceramics with favorable thermal conductivity. The ceramics are made of, for example, a material containing aluminum oxide, aluminum nitride, or silicon nitride as a main component. The insulating plate 21 is rectangular in shape in plan view. Examples of the insulated circuit board 20 that includes the insulating plate 21 with the configuration described above include a direct copper bonding (DCB) substrate and an active metal brazed (AMB) substrate.

Alternatively, the insulating plate 21 may be made of resin. The resin used may be a material that has low thermal resistance but is a favorable electrical insulator. Example resins include a thermosetting resin. The thermosetting resin may further contain a filler. It is possible to further reduce the thermal resistance of the insulating plate 21 by controlling the material and content of the filler. Depending on the material and content of the filler, the linear expansion coefficient of the insulating plate 21 is made substantially equal to the linear expansion coefficients of the heat dissipation plate 22 and the conductive circuit patterns 23a and 23b described later. By reducing the difference in the linear expansion coefficients in this way, it is possible to reduce warping of the insulated circuit board 20 due to differences in linear expansion coefficients, even when thermal changes occur. Note that when doing so, the difference in linear expansion coefficients may be within an error range of 10% or higher and 50% or lower.

Examples of the thermosetting resin include at least one of epoxy resin, cyanate resin, polyimide resin, benzoxazine resin, unsaturated polyester resin, phenol resin, melamine resin, silicone resin, maleimide resin, acrylic resin, and polyamide resin. The filler is made of at least one of an oxide and a nitride. Example oxides include silicon oxide and aluminum oxide. Example nitrides include silicon nitride, aluminum nitride, and boron nitride. Hexagonal boron nitride may also be used as the filler.

The thickness of the insulating plate 21 depends on the rated voltage of the semiconductor device 1. That is, the thickness of the insulating plate 21 needs to be increased as the rated voltage of the semiconductor device 1 increases. On the other hand, it is also important to make the insulating plate 21 as thin as possible to reduce thermal resistance.

The heat dissipation plate 22 is made of a metal with superior thermal conductivity. Example materials include copper, aluminum, and an alloy containing at least one of such metals. In this example, the material contains copper. In addition, to improve corrosion resistance, a plating process may be performed on the surface of the heat dissipation plate 22. The plating material in this case contains nickel. Example plating materials include nickel, nickel-phosphorus alloy, and nickel-boron alloy. The heat dissipation plate 22 includes a heat dissipation surface 22a on a lower surface thereof. The heat dissipation surface 22a may be substantially flat. The heat dissipation surface 22a is also the lower surface of the insulated circuit board 20. The heat dissipation surface 22a of the heat dissipation plate 22 is exposed from an encapsulating lower surface 35a of the encapsulating member 35, described later. In this case, the heat dissipation surface 22a of the heat dissipation plate 22 may protrude outward from the encapsulating lower surface 35a of the encapsulating member 35, or may be flush with the encapsulating lower surface 35a of the encapsulating member 35. In the present embodiment, the heat dissipation surface 22a of the heat dissipation plate 22 is flush with the encapsulating lower surface 35a of the encapsulating member 35.

The semiconductor chips 10a and 10b and the semiconductor chips 10d and 10e are disposed on the conductive circuit patterns 23a and 23b, respectively. The conductive circuit patterns 23a and 23b are formed over the entire surface of the insulating plate 21 except for edge portions thereof. It is preferable for end portions of the conductive circuit patterns 23a and 23b that face the outer periphery of the insulating plate 21 to coincide with outer peripheral end portions of the heat dissipation plate 22 in plan view. This means that stress is kept balanced between the insulated circuit board 20 and the heat dissipation plate 22 on the rear surface of the insulating plate 21. This further suppresses damage such as excessive warping and cracking of the insulating plate 21.

The conductive circuit patterns 23a and 23b are made of a material with superior electrical conductivity. Example materials include copper, aluminum, and an alloy containing at least one of such metals. The conductive circuit patterns 23a and 23b may be plated with a material with superior corrosion resistance. Example materials include nickel, nickel-phosphorus alloy, and nickel-boron alloy. The conductive circuit patterns 23a and 23b are obtained on the insulating plate 21 by forming a metal plate on the front surface of the insulating plate 21 and performing a process such as etching on the metal plate. Alternatively, conductive circuit patterns 23a and 23b that have been cut out from a metal plate in advance may be bonded to the front surface of the insulating plate 21. Note that the conductive circuit patterns 23a and 23b included in the semiconductor device 1 of the present embodiment are mere examples. The number, shape, size, and the like of the conductive circuit patterns may be appropriately selected as needed.

Although not illustrated in detail, the printed circuit board 30 includes an insulating layer and a plurality of upper circuit pattern layers formed on a front surface of the insulating layer. The printed circuit board 30 may also include a plurality of lower circuit pattern layers on the rear surface of the insulating layer. The printed circuit board 30 faces the front surface of the insulated circuit board 20 in plan view. The printed circuit board 30 is electrically connected to the output electrodes, the input electrodes, and the control electrodes of the semiconductor chips 10a, 10b, 10d, and 10e. Conductive posts 31a, 31b, 31d, and 31e depicted in FIG. 1 are mere examples, and additional conductive posts not depicted in FIG. 1 may also be included. Upper portions of the conductive posts 31a, 31b, 31d, and 31e and any non-depicted conductive posts are electrically connected to the upper circuit pattern layer and the lower circuit pattern layer of the printed circuit board 30. Lower portions of the posts are connected by solder 32 to the output electrodes and the control electrodes of the semiconductor chips 10a, 10b, 10d, and 10e. The solder component of the solder 32 is also the same as the solder component of the solder 12. In place of the solder 32, sintered metal described earlier may be used.

As one example, the printed circuit board 30 is electrically connected via the conductive posts 31a and 31b to the output electrodes on the front surfaces of the semiconductor chips 10a and 10b. The printed circuit board 30 is also electrically connected via the conductive posts 31d and 31e to the output electrodes on the front surfaces of the semiconductor chips 10d and 10e.

The printed circuit board 30 is electrically connected via the conductive post 31c and the conductive circuit pattern 23a to the input electrodes on the rear surfaces of the semiconductor chips 10a and 10b. In addition, the printed circuit board 30 is electrically connected via the conductive post 31f and the conductive circuit pattern 23b to the input electrodes on the rear surfaces of the semiconductor chips 10d and 10e.

The printed circuit board 30 is electrically connected via conductive posts (not depicted) to the control electrodes of the semiconductor chips 10a and 10b. The printed circuit board 30 is also electrically connected via conductive posts (not depicted) to the control electrodes of the semiconductor chips 10d and 10e.

The encapsulating member 35 encapsulates all of the insulated circuit board 20, the semiconductor chips 10a, 10b, 10d, and 10e, and the printed circuit board 30. As needed, various terminals for input, output, and control, for example, may protrude from the upper surface of the encapsulating member 35. The encapsulating member 35 may be shaped as a rectangular cuboid and include the flat encapsulating lower surface 35a. The heat dissipation surface 22a of the heat dissipation plate 22 of the insulated circuit board 20 is exposed from the encapsulating lower surface 35a of the encapsulating member 35.

The encapsulating member 35 may be a thermosetting resin containing a filler. That is, the encapsulating member 35 may have an electrically insulating filler, described later, and a resin (thermosetting resin) as main components. In this case, the thermosetting resin is epoxy resin, phenol resin, maleimide resin, or polyester resin, for example. The filler may contain electrically insulating ceramics with high thermal conductivity as a main component. Examples of the filler include silicon oxide, aluminum oxide, boron nitride, and aluminum nitride. The content of the filler is 10% by volume or higher and 70% by volume or lower with respect to the encapsulating member 35 as a whole.

The semiconductor module 2 with the configuration described above is merely one example. Although not depicted, in another example, the semiconductor module 2 may be configured by sequentially disposing a DCB substrate and semiconductor chips on a heat dissipation base, wiring the DCB substrate and the semiconductor chips, disposing a case that surrounds such components on the heat dissipation base, and encapsulating the inside of the case with an encapsulating member. For this configuration, the lower surface of the heat dissipation base corresponds to the heat dissipation surface 22a of the heat dissipation plate 22.

The cooling module 3 includes, on an upper surface thereof, the cooling surface 3a on which the heat dissipation surface 22a of the semiconductor module 2 is disposed. The cooling surface 3a is wider than the encapsulating lower surface 35a, which is the rear surface of the semiconductor module 2, and is substantially flat. As one example, the cooling module 3 may be a heat dissipation base including heat dissipation fins or a cooling device in which a refrigerant internally circulates.

The bonding member 4 is provided between the heat dissipation surface 22a of the heat dissipation plate 22 of the semiconductor module 2 and the cooling surface 3a of the cooling module 3. The shape and size of the bonding member 4 in plan view in the −Z direction substantially match the shape and size of the heat dissipation surface 22a of the heat dissipation plate 22. The bonding member 4 may contact the encapsulating lower surface 35a in the periphery of the heat dissipation surface 22a of the semiconductor module 2. The maximum size of the bonding member 4 in plan view in the −Z direction may correspond to the encapsulating lower surface 35a of the semiconductor module 2.

The bonding member 4 includes a thermally conductive part 4a and an electrically conductive part 4b. The thermally conductive part 4a thermally connects the heat dissipation surface 22a of the heat dissipation plate 22 and the cooling surface 3a of the cooling module 3. As depicted in FIGS. 1 and 2, in plan view, the thermally conductive part 4a is provided inside the cooling surface 3a of the cooling module 3 (and the heat dissipation surface 22a of the semiconductor module 2) and is in a similar rectangular shape to the cooling surface 3a (and the heat dissipation surface 22a). The corners of the rectangular thermally conductive part 4a may be chamfered into rounded shapes. The shape of the thermally conductive part 4a in plan view is not limited to a rectangular shape so long as the thermally conductive part 4a is included in an inner region of the cooling surface 3a of the cooling module 3.

The thermally conductive part 4a may be made of a material with thermally conductive, electrically insulating, and adhesive properties. The thermal conductivity may be 10 W/mK or higher. The material may be selected so as to achieve this thermal conductivity. The adhesive strength is 10 MPa or higher, for example. Note that the adhesive strength referred to here is tensile adhesive strength. This material contains resin as a main component, for example. As one example, the resin may be epoxy resin. Accordingly, the thermally conductive part 4a of the bonding member 4 is bonded to the heat dissipation surface 22a of the heat dissipation plate 22 and to the cooling surface 3a of the cooling module 3.

The electrically conductive part 4b directly connects to the heat dissipation plate 22 and the cooling surface 3a of the cooling module 3. In the first embodiment, as depicted in FIG. 2, the electrically conductive part 4b has a continuous annular shape on the cooling surface 3a of the cooling module 3 in plan view, and is provided so as to surround the periphery of the thermally conductive part 4a. That is, the electrically conductive part 4b is in continuous annular contact around the outer edge of the heat dissipation surface 22a of the heat dissipation plate 22 of the semiconductor module 2. In other words, in plan view, the outer periphery of the electrically conductive part 4b may substantially coincide with the outer periphery of the heat dissipation surface 22a of the heat dissipation plate 22. Here, the entire boundary of the electrically conductive part 4b with the thermally conductive part 4a is in contact with the thermally conductive part 4a. Note that outer corner portions of the electrically conductive part 4b may be chamfered into rounded shapes. Since the corner portions of the thermally conductive part 4a and the electrically conductive part 4b of the bonding member 4 are rounded in this way, it is possible to prevent the concentration of stress at the corner portions. By doing so, it is possible to suppress delamination of the bonding member 4 from the heat dissipation surface 22a and the cooling surface 3a.

The electrically conductive part 4b is made of an electrically conductive member and preferably has an adhesive property. Examples of such a conductive member include the solder mentioned earlier, a paste of metal particles, and electrically conductive adhesive. Example pastes of metal particles include a paste of silver, copper, or an alloy containing at least one of these metals. The size of the particles may be less than 10 μm. The electrically conductive adhesive may be made of the same main component as the thermally conductive part 4a, and contains an electrically conductive filler. As one example, the electrically conductive filler may be a metal. Example metals include silver, copper, gold, nickel, chromium, aluminum, and an alloy containing at least one of these metals. When the base material of the electrically conductive part 4b is the same as the thermally conductive part 4a, the adhesion between the electrically conductive part 4b and the thermally conductive part 4a is improved. When the electrically conductive part 4b has higher rigidity than the thermally conductive part 4a, the thermally conductive part 4a is fixed by the electrically conductive part 4b due to the electrically conductive part 4b physically surrounding the thermally conductive part 4a. This prevents delamination of the thermally conductive part 4a.

With this bonding member 4, heat generated from the semiconductor module 2 is conducted from the heat dissipation surface 22a of the heat dissipation plate 22 to the cooling surface 3a of the cooling module 3 via the thermally conductive part 4a, thereby cooling the semiconductor module 2. The heat dissipation surface 22a of the heat dissipation plate 22 of the semiconductor module 2 is also electrically connected to the cooling surface 3a of the cooling module 3 via the electrically conductive part 4b. That is, due to the electrically conductive part 4b, the heat dissipation plate 22 of the semiconductor module 2 and the cooling surface 3a of the cooling module 3 are placed at the same potential.

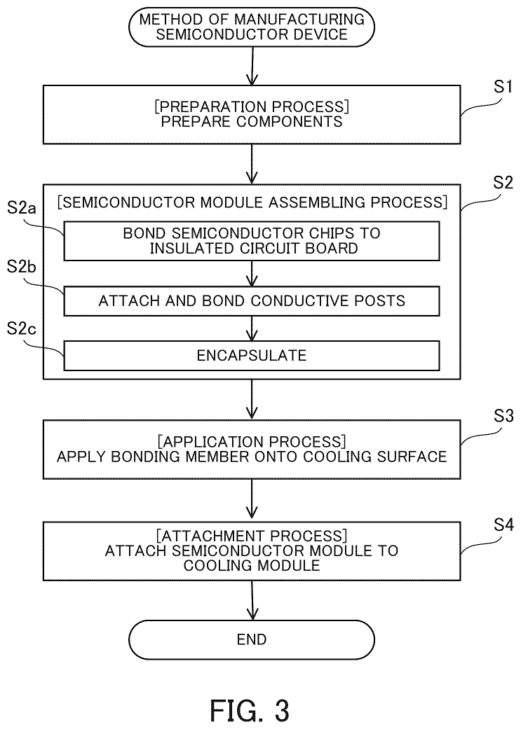

Next, a method of manufacturing the semiconductor device 1 described above will be described with reference to FIG. 3. FIG. 3 is a flowchart depicting a method of manufacturing the semiconductor device according to the first embodiment. First, a preparation process of preparing the components of the semiconductor device 1 is performed (step S1). As examples, the components prepared here include the semiconductor chips 10a, 10b, 10d, and 10e that construct the semiconductor module 2, the insulated circuit board 20, the printed circuit board 30 provided with the conductive posts 31a, 31b, 31c, 31d, 31e, and 31f, the encapsulating member 35, and the bonding member 4. The cooling module 3 may be given as another example of a prepared component. Other components that are not listed here but are needed to manufacture the semiconductor device 1 may also be prepared. Manufacturing apparatuses used for manufacturing the semiconductor device 1 may also be prepared. Examples of such manufacturing apparatuses include an application apparatus for applying solder and a molding apparatus for encapsulating with an encapsulating member.

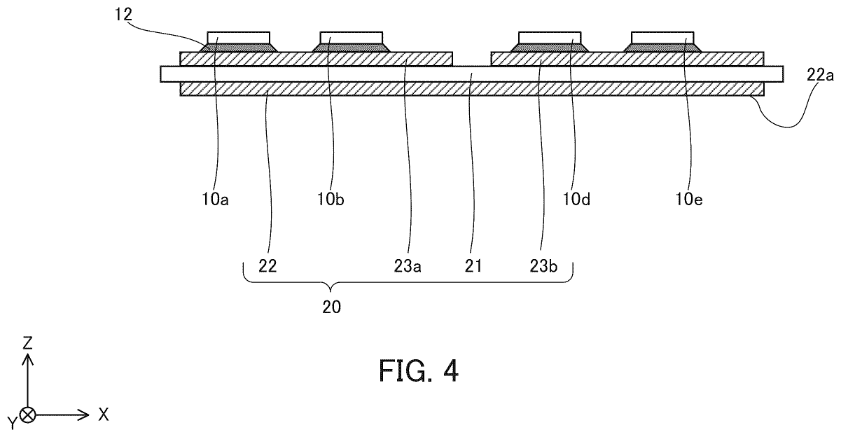

Next, a semiconductor module assembling process of assembling the semiconductor module 2 is performed (step S2). In the semiconductor module assembling process, the following processes are performed. First, the semiconductor chips 10a, 10b, 10d, and 10e are bonded to the insulated circuit board 20 (step S2a). Step S2a will be described with reference to FIG. 4. FIG. 4 is a diagram useful in explaining a semiconductor module assembling process according to the first embodiment.

The semiconductor chips 10a, 10b, 10d, and 10e are bonded via the solder 12 to the conductive circuit patterns 23a and 23b of the insulated circuit board 20. This bonding may be performed by conventional solder bonding. By doing so, as depicted in FIG. 4, a structure is obtained in which the semiconductor chips 10a and 10b are bonded via the solder 12 to the conductive circuit pattern 23a of the insulated circuit board 20, and the semiconductor chips 10d and 10e are bonded via the solder 12 to the conductive circuit pattern 23b.

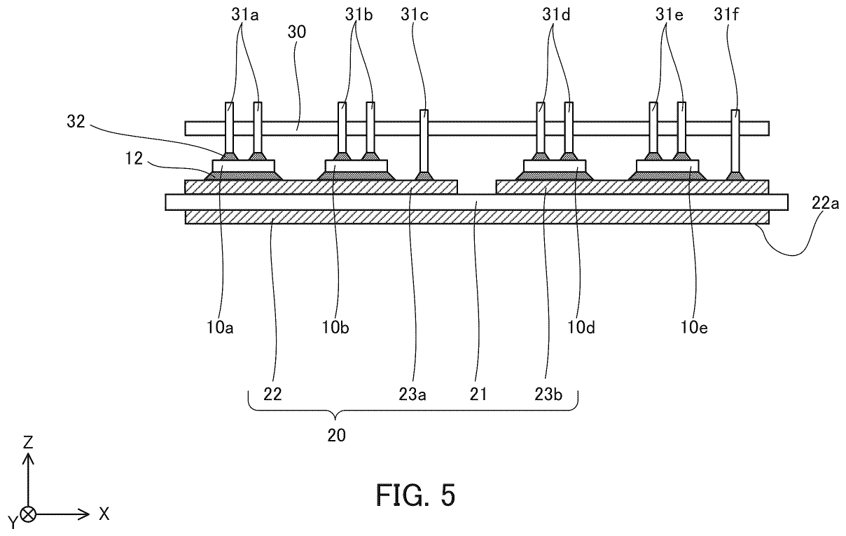

After this, the conductive posts 31a, 31b, 31c, 31d, 31e, and 31f of the printed circuit board 30 are bonded to the semiconductor chips 10a and 10b, the conductive circuit pattern 23a of the insulated circuit board 20, the semiconductor chips 10d and 10e, and the conductive circuit pattern 23b of the insulated circuit board 20 (step S2b). Step S2b will now be described with reference to FIG. 5. FIG. 5 is a diagram useful in explaining the semiconductor module assembling process according to the first embodiment.

The conductive posts 31a, 31b, 31c, 31d, 31e, and 31f are provided on the printed circuit board 30 in advance. The conductive posts 31a, 31b, 31c, 31d, 31e, and 31f are bonded to the semiconductor chips 10a and 10b, the conductive circuit pattern 23a of the insulated circuit board 20, the semiconductor chips 10d and 10e, and the conductive circuit pattern 23b of the insulated circuit board 20 by the solder 32 using conventional solder bonding. By doing so, as depicted in FIG. 5, a structure in which the printed circuit board 30 is attached to the insulated circuit board 20 to which the semiconductor chips 10a, 10b, 10d, and 10e have been bonded is obtained.

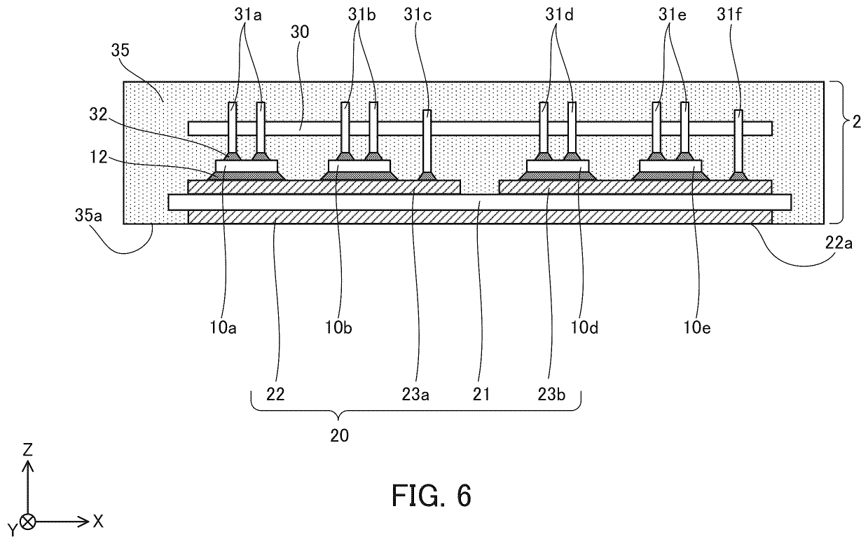

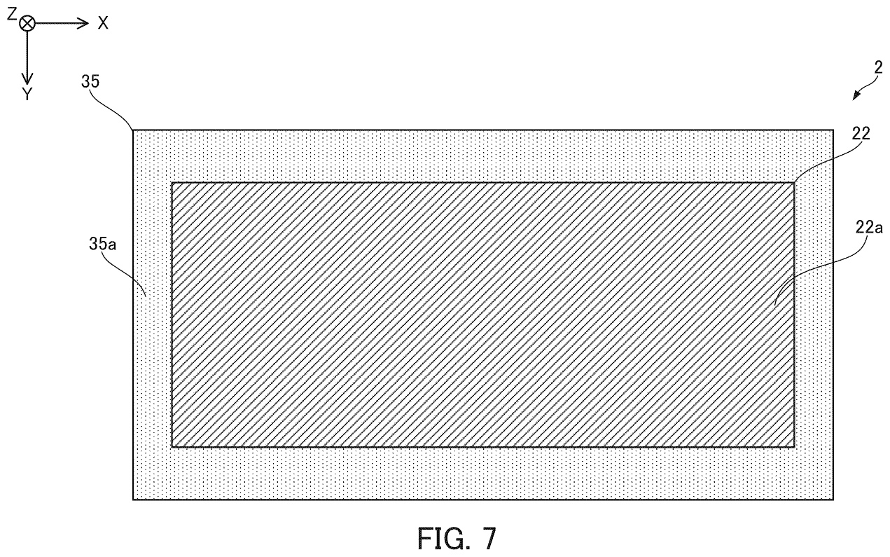

As the final process of step S2, encapsulating is performed with the encapsulating member 35 (step S2c). Step S2c will now be described with reference to FIGS. 6 and 7. FIG. 6 is a side sectional view of the semiconductor module according to the first embodiment. FIG. 7 is a rear view of the semiconductor module according to the first embodiment. Note that FIG. 7 is a plan view of the encapsulating lower surface 35a of the semiconductor module 2 when the semiconductor module 2 of FIG. 6 is viewed in the +Z direction.

The structure obtained in step S2b is set inside a predetermined mold, for example. The mold is filled with the encapsulating member 35 to encapsulate the structure. By removing the mold, the semiconductor module 2 depicted in FIG. 6 is obtained. In the semiconductor module 2, as depicted in FIG. 7, the heat dissipation surface 22a of the heat dissipation plate 22 of the insulated circuit board 20 is exposed from the encapsulating lower surface 35a of the encapsulating member 35. The encapsulating lower surface 35a of the encapsulating member 35 and the heat dissipation surface 22a of the heat dissipation plate 22 are flush with each other. The rear surface of the semiconductor module 2 is formed by the encapsulating lower surface 35a of the encapsulating member 35 and the heat dissipation surface 22a of the heat dissipation plate 22.

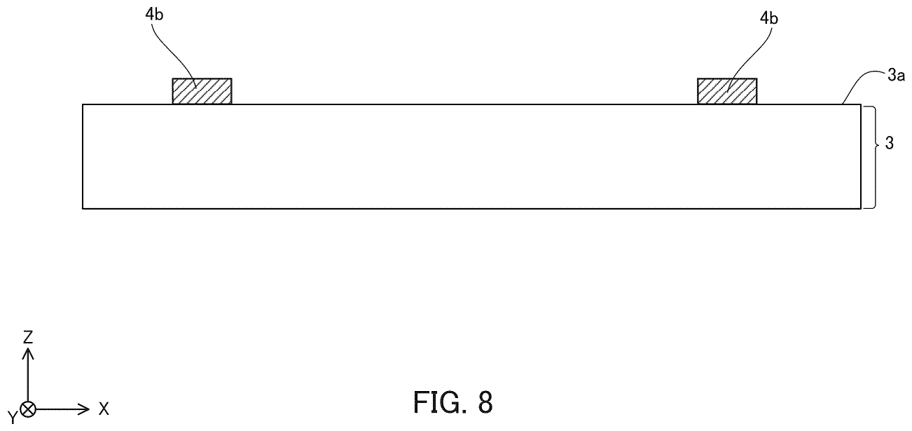

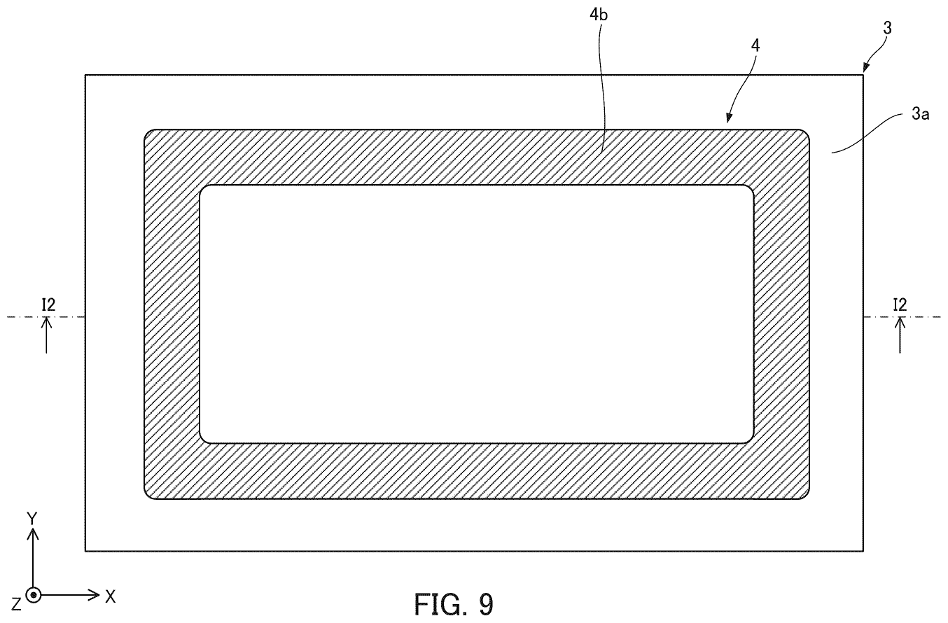

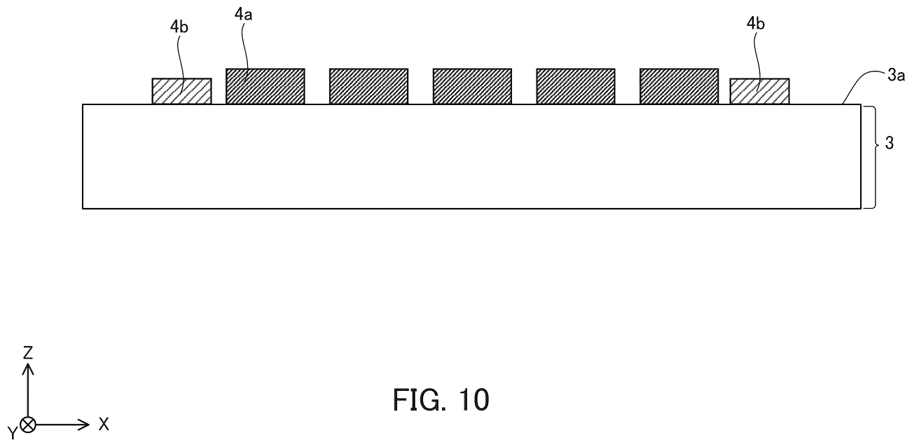

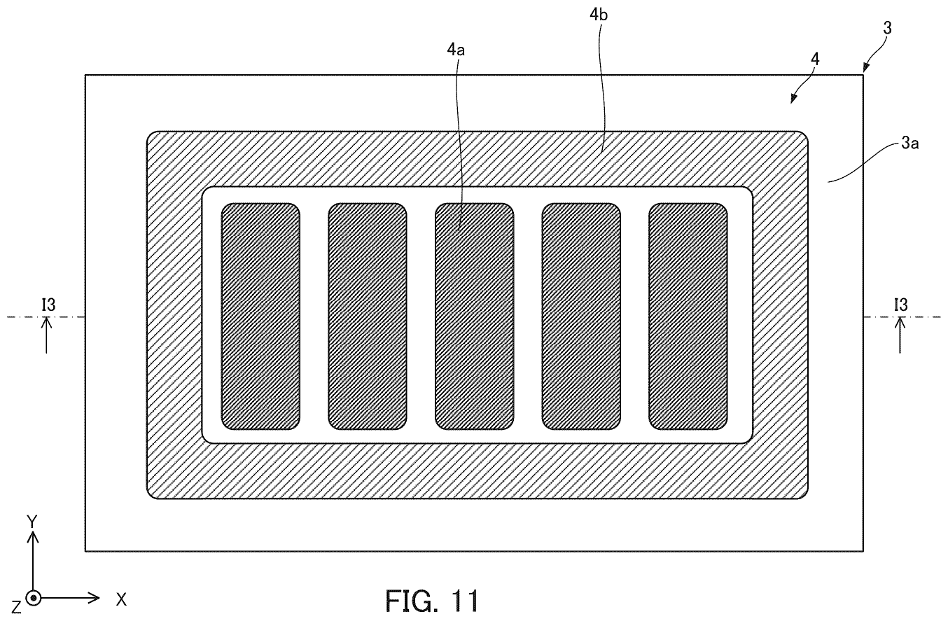

Next, an application process of applying the bonding member 4 is performed (step S3). The bonding member 4 may be applied to either the heat dissipation surface 22a of the semiconductor module 2 or to the cooling surface 3a of the cooling module 3. Here, a case where the bonding member 4 is applied to the cooling surface 3a of the cooling module 3 will be described with reference to FIGS. 8 to 11. FIGS. 8 to 11 are diagrams useful in explaining an application process in the first embodiment. FIGS. 8 and 10 are cross-sectional views taken along the chain lines I2-I2 and I3-I3 in FIGS. 9 and 11, respectively.

First, the electrically conductive part 4b is applied to the cooling surface 3a of the cooling module 3. When applying the electrically conductive part 4b to the cooling surface 3a, as one example, a mask with an opening in an application region of the cooling surface 3a of the cooling module 3 is set on the cooling surface 3a of the cooling module 3. The electrically conductive part 4b is applied in the opening using a squeegee. When the mask is removed, the electrically conductive part 4b is transferred to the application area, as illustrated in FIGS. 8 and 9. In this case, as described earlier, the electrically conductive part 4b is applied to the cooling surface 3a in a continuous annular shape corresponding to the outer edge of the heat dissipation surface 22a. Note that the applying described here may be performed using a dispenser or a syringe in place of a mask and a squeegee.

Next, the thermally conductive part 4a is applied to the cooling surface 3a of the cooling module 3. As one example, a syringe is used to apply the thermally conductive part 4a to the inside of the region on the cooling surface 3a surrounded by the electrically conductive part 4b. As a result, as depicted in FIGS. 10 and 11, the thermally conductive part 4a is applied, for example, to five locations within the region surrounded by the electrically conductive part 4b. When doing so, the five thermally conductive parts 4a are applied so as to be spaced apart. The five thermally conductive parts 4a are also spaced apart from the electrically conductive part 4b. Note that with consideration to five thermally conductive parts 4a then being pressed and spreading out, as one example, the thermally conductive parts 4a may be applied so as to be higher than the electrically conductive part 4b.

Next, an attachment process of attaching the heat dissipation surface 22a of the heat dissipation plate 22 of the semiconductor module 2 via the bonding member 4 to the cooling surface 3a of the cooling module 3 is performed (step S4). First, the cooling module 3 onto which the bonding member 4 has been applied is fixed to a predetermined fixing base, and the semiconductor module 2 is set onto the bonding member 4 applied onto the cooling module 3 from the encapsulating lower surface 35a side. By doing so, the thermally conductive part 4a becomes spread out inside the electrically conductive part 4b.

The structure including the cooling module 3 and the semiconductor module 2 that has been disposed via the bonding member 4 on the cooling surface 3a of the cooling module 3 is then heated. When doing so, the heating temperature is 200° C. or less, for example. By doing so, remelting of the solder 12 and 32 in the semiconductor module 2 is suppressed. During this process, the semiconductor module 2 is pressed toward the cooling module 3 at a constant pressure. By doing so, it is possible to control the thickness of the bonding member 4. By heating in this manner, the thermally conductive part 4a of the bonding member 4 is hardened, thereby bonding the semiconductor module 2 and the cooling module 3. Through the processes described above, the semiconductor device 1 depicted in FIGS. 1 and 2 is obtained.

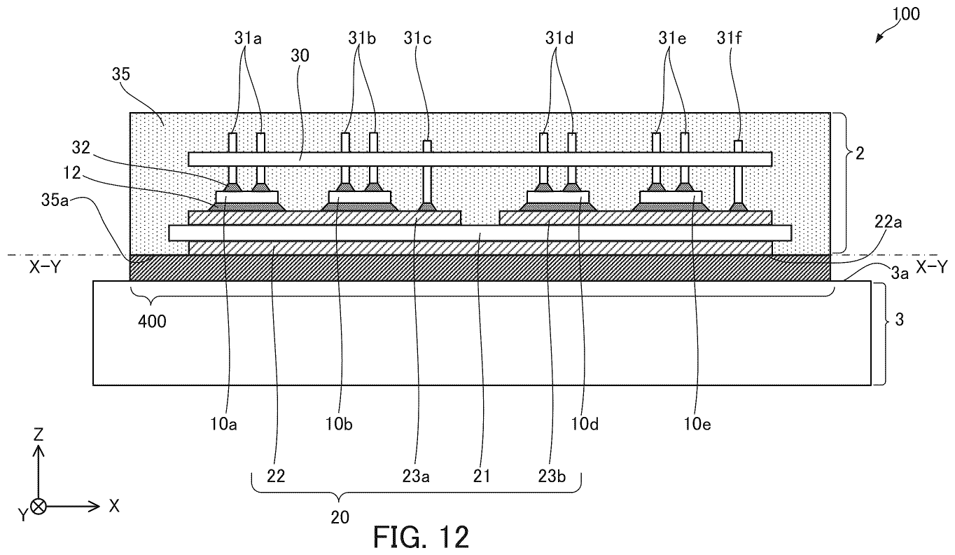

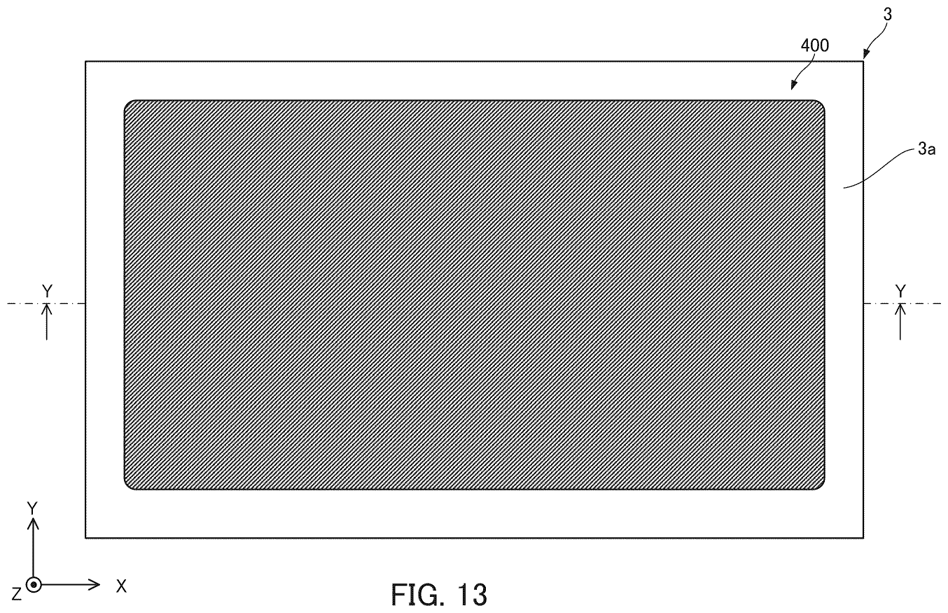

Here, a semiconductor device 100 that is a comparative example will be described with reference to FIGS. 12 and 13. FIG. 12 is a side sectional view of a semiconductor device according to a comparative example. FIG. 13 is a plan view of a cooling surface of the semiconductor device according to the comparative example. Note that FIGS. 12 and 13 correspond to FIGS. 1 and 2. Accordingly, FIG. 13 is a cross-sectional view of the semiconductor device 100 in FIG. 12 taken along the X-Y plane indicated by a chain line. That is, FIG. 13 is a plan view of the cooling surface 3a of the cooling module 3 on which a bonding member 400 has been applied. FIG. 12 is a cross-sectional view taken along the chain line Y-Y in FIG. 13 and when looking in the +Y direction.

In the semiconductor device 100 according to the comparative example, the bonding member 400 is used in place of the bonding member 4 of the semiconductor device 1. The semiconductor device 100 has the same configuration as the semiconductor device 1 except for the bonding member 400.

The bonding member 400 may be a thermal interface material (TIM). The TIM used here is an electrically insulating material such as thermally conductive grease, an elastomer sheet, room temperature vulcanization (RTV) rubber, gel, or a phase change material. The bonding member 400 is in contact with the entire encapsulating lower surface 35a of the semiconductor module 2 and bonds the semiconductor module 2 and the cooling module 3.

This semiconductor device 100 has a power converting function and has a high voltage applied to it. Polarization occurs within the bonding member 400, so that a potential difference is generated between the heat dissipation plate 22 and the cooling module 3. When this happens and voids are present in the bonding member 400, there is the risk of corona discharge occurring. When corona discharge occurs, damage such as holes may be produced in the cooling surface 3a of the cooling module 3 or the bonding member 400. Such damage may result in the heat dissipation plate 22 and the cooling module 3 becoming electrically connected to each other, which reduces the reliability of the semiconductor device 100.

The semiconductor device 1 described above includes the heat dissipation plate 22 including the heat dissipation surface 22a, the cooling module 3 including the cooling surface 3a on which the heat dissipation surface 22a of the heat dissipation plate 22 is disposed, and the bonding member 4 provided between the heat dissipation surface 22a and the cooling surface 3a. The bonding member 4 includes the thermally conductive part 4a, which bonds the heat dissipation surface 22a and the cooling surface 3a, and the electrically conductive part 4b, which directly connects the heat dissipation plate 22 and the cooling surface 3a. This makes it possible to set the heat dissipation plate 22 and the cooling module 3 at the same potential, which prevents corona discharge from occurring. This makes the semiconductor device 1 electrically stable and prevents a drop in reliability.

To prevent the occurrence of corona discharge, it is sufficient for the bonding member 4 to include the electrically conductive part 4b, and the TIM described in the comparative example may be used as the thermally conductive part 4a. This means that the range of choice for the thermally conductive part 4a of the bonding member 4 is increased.

In addition, since it is sufficient for the bonding member 4 to include the electrically conductive part 4b, the electrically conductive part 4b does not need to be provided in the outer periphery of the bonding member 4 and does not need to have a continuous annular shape. The electrically conductive part 4b may be included at a part of the bonding member 4 that directly connects the heat dissipation plate 22 and the cooling surface 3a, and may be any shape capable of forming a direct connection.

Alternatively, the electrically conductive part 4b may be introduced into the bonding member 4 by forming the entire bonding member 4 from a predetermined base material and biasing the distribution of the conductive filler described earlier included in the base material of the bonding member 4.

### Second Embodiment

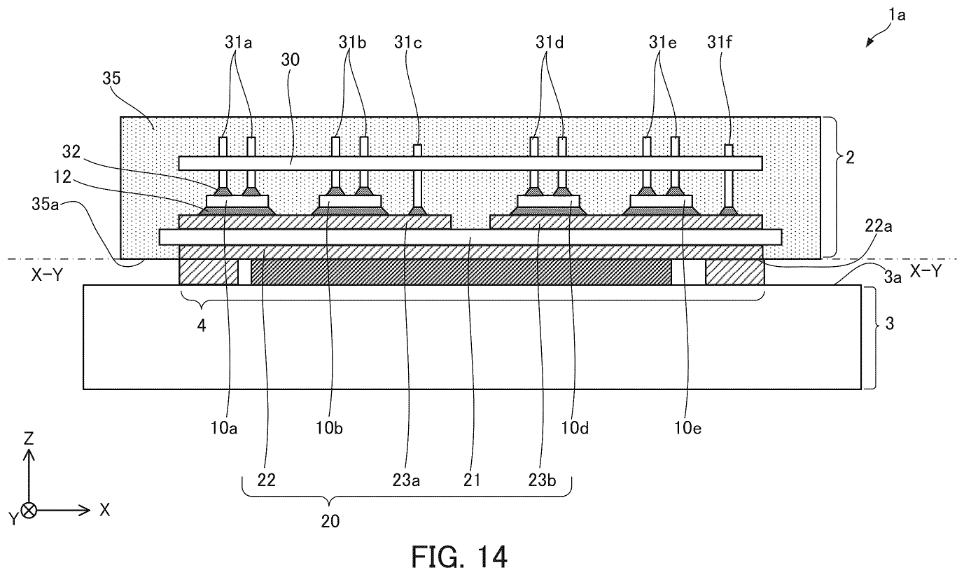

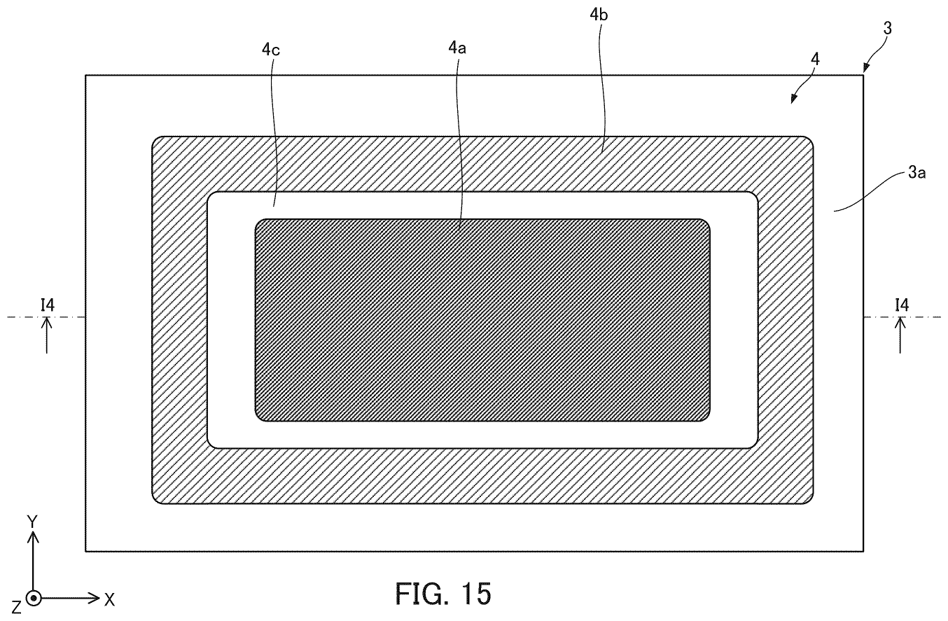

A semiconductor device according to a second embodiment will now be described with reference to FIGS. 14 and 15. FIG. 14 is a side sectional view of a semiconductor device according to the second embodiment. FIG. 15 is a plan view of a cooling surface of the semiconductor device according to the second embodiment. Note that FIGS. 14 and 15 correspond to FIGS. 1 and 2. Accordingly, FIG. 15 is a cross-sectional view of a semiconductor device 1a in FIG. 14 taken along the X-Y plane indicated by a chain line. That is, FIG. 15 is a plan view of the cooling surface 3a of the cooling module 3. FIG. 14 is a cross-sectional view taken along a chain line I4-I4 in FIG. 15, when looking in the +Y direction.

As in the semiconductor device 1 according to the first embodiment, the semiconductor device 1a includes the semiconductor module 2, the cooling module 3, and the bonding member 4. The bonding member 4 also includes the thermally conductive part 4a and the electrically conductive part 4b. However, in the bonding member 4 according to the second embodiment, the thermally conductive part 4a and the electrically conductive part 4b are not in contact with each other and there is a gap in between. As one example, as depicted in FIGS. 14 and 15, the electrically conductive part 4b is continuously provided in an annular shape around the outer edge of the heat dissipation surface 22a of the heat dissipation plate 22 in the same way as in the first embodiment. On the other hand, the thermally conductive part 4a has a rectangular shape in plan view, and is provided inside the electrically conductive part 4b with a gap 4c from an inner surface of the electrically conductive part 4b. Note that it is sufficient for the thermally conductive part 4a to be provided with the gap 4c from the electrically conductive part 4b, and the thermally conductive part 4a is not limited to the shape depicted in FIGS. 14 and 15. The gap 4c also depends on the shape of the thermally conductive part 4a, with the shape depicted in FIGS. 14 and 15 as merely one example.

During the manufacturing process of the semiconductor device 1a, the thermally conductive part 4a of the bonding member 4 may expand or contract in keeping with thermal changes during the operation of the semiconductor device 1a. In particular, when the thermally conductive part 4a expands, there is the risk of leaking to the outside. When the thermally conductive part 4a leaks to the outside, the periphery of the semiconductor device 1a becomes contaminated, resulting in loss. The semiconductor device 1a according to the second embodiment prevents leakage of the thermally conductive part 4a and thereby prevents adverse effects on the periphery and loss. Note that the gap 4c between the electrically conductive part 4b and the thermally conductive part 4a does not need to be annular. It is sufficient to provide space as clearance for the thermally conductive part 4a that thermally expands.

### Third Embodiment

A method of manufacturing the semiconductor device 1b according to a third embodiment will now be described with reference to FIG. 3 mentioned earlier. As will be described later, the semiconductor device 1b according to the third embodiment is manufactured with consideration to the insulated circuit board 20 becoming warped in a downwardly convex shape. The semiconductor device 1b is also formed according to the flowchart in FIG. 3 of the first embodiment. The explanation below will mainly focus on manufacturing processes that differ from the first embodiment.

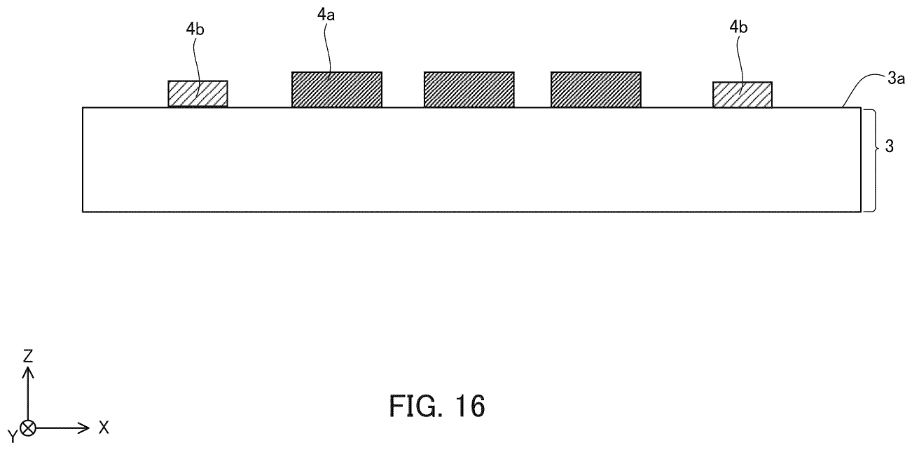

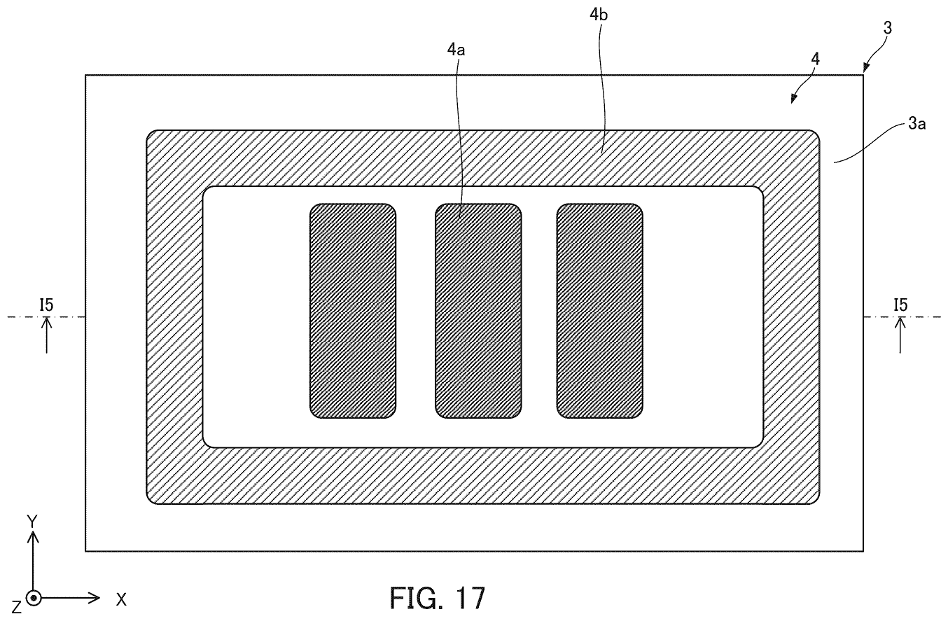

After steps S1 and S2 described in FIG. 3, an application step of applying the bonding member 4 is performed (step S3). The bonding member 4 may be applied to either the heat dissipation surface 22a of the semiconductor module 2 or the cooling surface 3a of the cooling module 3. Here, a case where the material is applied to the cooling surface 3a of the cooling module 3 will be described with reference to FIGS. 16 and 17. FIGS. 16 and 17 are diagrams useful in explaining the application process in the third embodiment. Note that FIGS. 16 and 17 correspond to FIGS. 10 and 11. FIG. 16 is a cross-sectional view taken along a chain line I5-I5 in FIG. 17.

In this third embodiment also, as in the first embodiment, the electrically conductive part 4b is first applied to the cooling surface 3a of the cooling module 3. After this, the thermally conductive part 4a is applied to the cooling surface 3a of the cooling module 3. As one example, a syringe is used to apply the thermally conductive part 4a to a region inside the electrically conductive part 4b of the cooling surface 3a. By doing so, as depicted in FIGS. 16 and 17, the thermally conductive part 4a is applied to three locations for example in a region surrounded by the electrically conductive part 4b. The intervals between the thermally conductive parts 4a are wider than that in the first embodiment, and the total volume of the thermally conductive parts 4a is smaller than in the first embodiment.

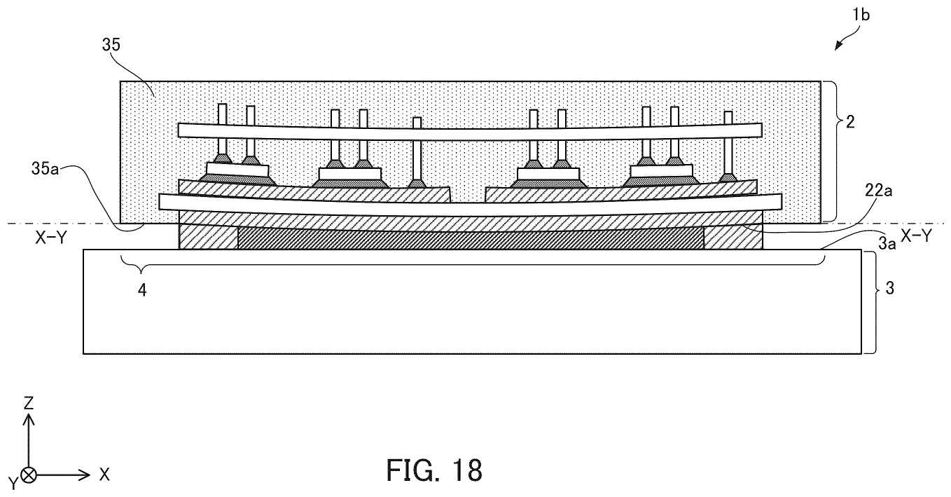

Next, an attachment process that attaches the heat dissipation surface 22a of the heat dissipation plate 22 of the semiconductor module 2 to the cooling surface 3a of the cooling module 3 via the bonding member 4 is performed (step S4). This attachment process will be described with reference to FIG. 18. FIG. 18 is a side sectional view of the semiconductor device according to the third embodiment. This attachment process is performed in the same way as in the first embodiment.

The semiconductor module 2 is set onto the bonding member 4 that has been applied on the cooling module 3 from the encapsulating lower surface 35a side. By doing so, the thermally conductive part 4a spreads out inside the electrically conductive part 4b. After this, as in the first embodiment, the structure including the cooling module 3 and the semiconductor module 2 disposed via the bonding member 4 on the cooling surface 3a of the cooling module 3 is heated. Due to this heating, the insulated circuit board 20 may warp to become downwardly convex due to differences in linear expansion coefficient between the insulating plate 21 and the heat dissipation plate 22 and conductive circuit patterns 23a and 23b. When the insulated circuit board 20 becomes downwardly warped in this way, pressure is applied to (the central portion in a plan view of) the thermally conductive part 4a. In this configuration, the thermally conductive part 4a is applied with a reduced amount compared with the first embodiment and the intervals are larger. This means that the pressed thermally conductive part 4a will not leak from the electrically conductive part 4b, and as depicted in FIG. 18, will fill the region formed by the heat dissipation surface 22a of the heat dissipation plate 22, the cooling surface 3a of the cooling module 3, and the electrically conductive part 4b. That is, the thermally conductive parts 4a used here may be disposed with intervals corresponding to the warping amount of the insulated circuit board 20 (see FIG. 17). Such intervals serve as clearance for the thermally conductive part 4a that is pressed due to the insulated circuit board 20 warping in a downwardly convex shape.

In the semiconductor device 1b manufactured in this way, the thermally conductive part 4a of the bonding member 4 does not leak out, and it is possible to bond the heat dissipation surface 22a of the downwardly warped heat dissipation plate 22 and the cooling surface 3a of the cooling module 3 without gaps, which suppresses any decrease in heat dissipation performance.

### Fourth Embodiment

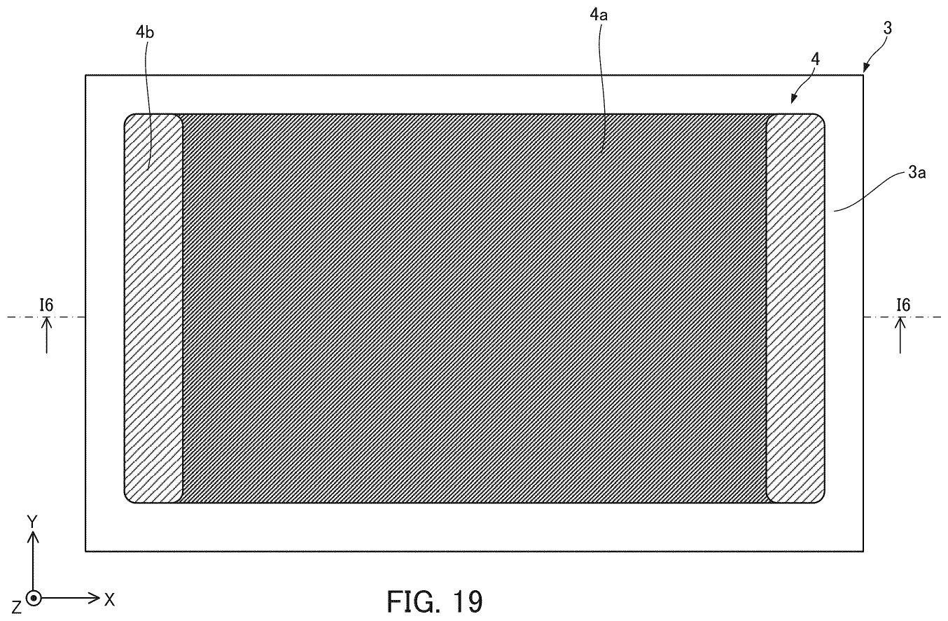

A semiconductor device according to a fourth embodiment will now be described with reference to FIG. 19. FIG. 19 is a plan view of a cooling surface of the semiconductor device according to the fourth embodiment. Note that FIG. 19 corresponds to FIG. 2. See FIG. 1 for a cross section of this semiconductor device taken along a chain line I6-I6 in FIG. 19.

As in the semiconductor device 1 according to the first embodiment, the semiconductor device 1a according to the fourth embodiment includes the semiconductor module 2 (not illustrated), the cooling module 3, and the bonding member 4. The bonding member 4 also includes the thermally conductive part 4a and the electrically conductive part 4b. However, in the bonding member 4 of the fourth embodiment, electrically conductive parts 4b that are linear are provided on the cooling surface 3a so as to face each other, and the thermally conductive part 4a is provided between these facing electrically conductive parts 4b. That is, the linear electrically conductive parts 4b that face each other correspond to the facing short sides of the heat dissipation surface 22a of the heat dissipation plate 22. The thermally conductive part 4a corresponds to the entire surface of the heat dissipation surface 22a between the facing electrically conductive parts 4b in plan view. In the fourth embodiment, the thermally conductive part 4a and the electrically conductive parts 4b are in contact with each other. Also in this case, gaps may be provided between the thermally conductive part 4a and the electrically conductive part 4b as in the second embodiment.

In the fourth embodiment, the facing electrically conductive parts 4b correspond to the facing short sides of the heat dissipation surface 22a. However, the embodiment is not limited to this configuration, and the electrically conductive parts 4b may correspond to the facing long sides of the heat dissipation surface 22a, and may correspond to at least one of one short side and one long side of the heat dissipation surface 22a. The thermally conductive part 4a may correspond to part or all of a range of the heat dissipation surface 22a in plan view aside from the electrically conductive part 4b.

Also in the fourth embodiment, the bonding member 4 includes the thermally conductive part 4a that bonds the heat dissipation surface 22a and the cooling surface 3a, and the electrically conductive part 4b that directly connects the heat dissipation plate 22 and the cooling surface 3a. This makes it possible to set the heat dissipation plate 22 and the cooling module 3 at the same potential, which prevents the occurrence of corona discharge. The semiconductor device according to this fourth embodiment is electrically stable, which prevents a drop in reliability.

### Fifth Embodiment

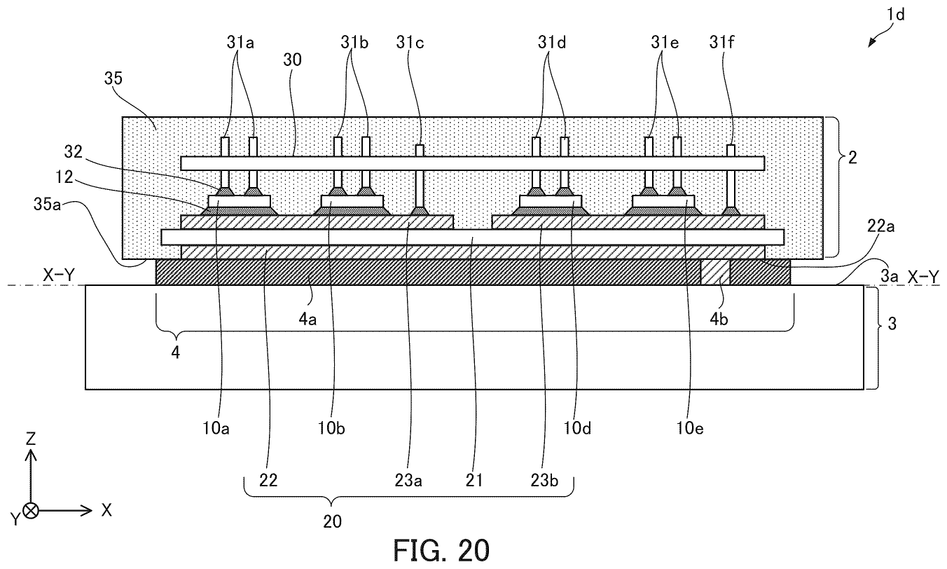

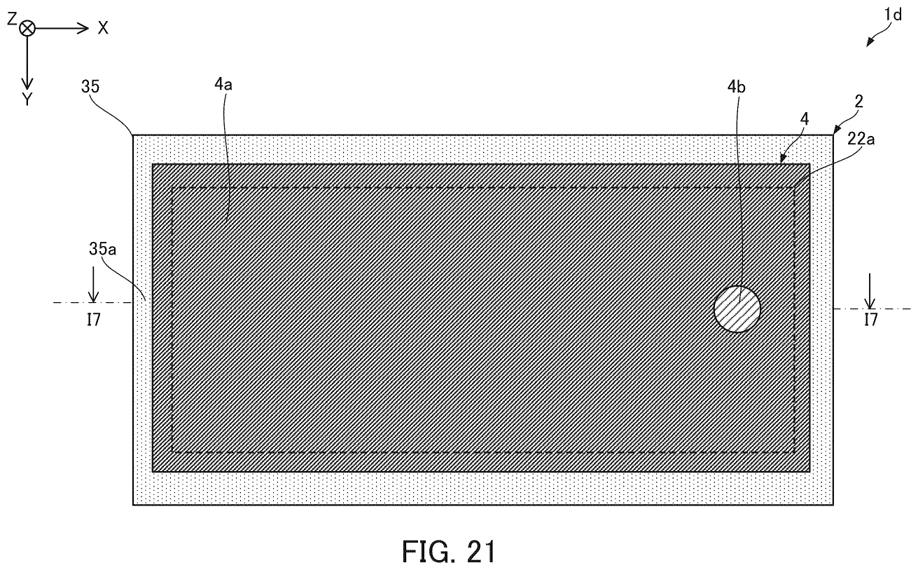

A semiconductor device 1d according to a fifth embodiment will now be described with reference to FIGS. 20 and 21. FIG. 20 is a side sectional view of the semiconductor device according to the fifth embodiment. FIG. 21 is a rear view of the semiconductor module according to the fifth embodiment. Note that FIG. 21 is a cross-sectional view of the semiconductor device 1d in FIG. 20 taken along the X-Y plane indicated by the chain line. That is, FIG. 21 is a plan view of the encapsulating lower surface 35a of the semiconductor module 2. In FIG. 21, the broken line drawn inside the thermally conductive part 4a indicates the position of the outer edge of the heat dissipation surface 22a. FIG. 20 is a cross-sectional view taken along a dashed-dotted line I7-I7 in FIG. 21, when looking in the +Y direction.

As in the semiconductor device 1 according to the first embodiment, a semiconductor device 1d according to the fifth embodiment includes the semiconductor module 2 and the cooling module 3. The bonding member 4 is provided between the encapsulating lower surface 35a of the semiconductor module 2 and the cooling surface 3a of the cooling module 3. This bonding member 4 also includes the thermally conductive part 4a and the electrically conductive part 4b.

The electrically conductive part 4b of the bonding member 4 according to the fifth embodiment is provided on the heat dissipation surface 22a of the heat dissipation plate 22 in plan view. One or a plurality of electrically conductive parts 4b may be provided as long as each part passes through the bonding member 4 (the thermally conductive part 4a) so as to directly connect the heat dissipation surface 22a of the heat dissipation plate 22 and the cooling surface 3a of the cooling module 3. The example of the electrically conductive part 4b depicted in FIGS. 20 and 21 is cylindrical in shape, and is provided as a single electrically conductive part 4b. The electrically conductive part 4b is not limited to a cylindrical shape and as other examples may be columnar shape including prismatic columns, or a truncated cone shape. The direction in which the electrically conductive part 4b connects the heat dissipation surface 22a and the cooling surface 3a is not limited to the vertical direction (the ±Z direction) and may be inclined with respect to the ±Z direction.

The thermally conductive part 4a may be provided on a part of the heat dissipation surface 22a aside from the part where the electrically conductive part 4b is provided in plan view. The thermally conductive part 4a in FIGS. 20 and 21 is provided in an inner region of the encapsulating lower surface 35a that includes the heat dissipation surface 22a but excludes the part where the electrically conductive part 4b is provided in plan view. That is, the thermally conductive part 4a is formed in a wider shape than the heat dissipation surface 22a in plan view. When the thermally conductive part 4a is made of the same base material as the encapsulating member 35, it is possible to achieve a certain adhesive strength for the bonding of the bonding member 4 (the thermally conductive part 4a) to the semiconductor module 2 due to the bonding member 4 (the thermally conductive part 4a) contacting the encapsulating lower surface 35a.

Also in the fifth embodiment, the bonding member 4 includes the thermally conductive part 4a which bonds the heat dissipation surface 22a and the cooling surface 3a, and the electrically conductive part 4b that directly connects the heat dissipation plate 22 and the cooling surface 3a. This makes it possible to set the heat dissipation plate 22 and the cooling module 3 at the same potential, which prevents the occurrence of corona discharge. It is also possible to reliably bond the semiconductor module 2 and the cooling module 3 with the bonding member 4. This makes the semiconductor device 1d electrically stable, makes the semiconductor module 2 and the cooling module 3 less likely to delaminate, and prevents a drop in reliability.

Note that FIGS. 20 and 21 depict a configuration where the periphery of the electrically conductive part 4b is in contact with and surrounded by the thermally conductive part 4a. However, a gap may be provided at the boundary between the electrically conductive part 4b and the thermally conductive part 4a as in the second embodiment.

### Sixth Embodiment

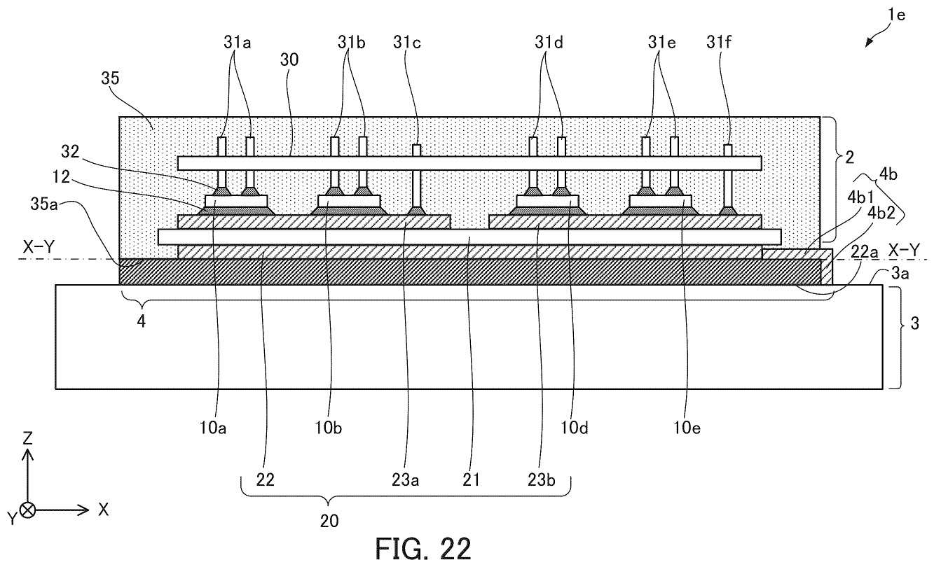

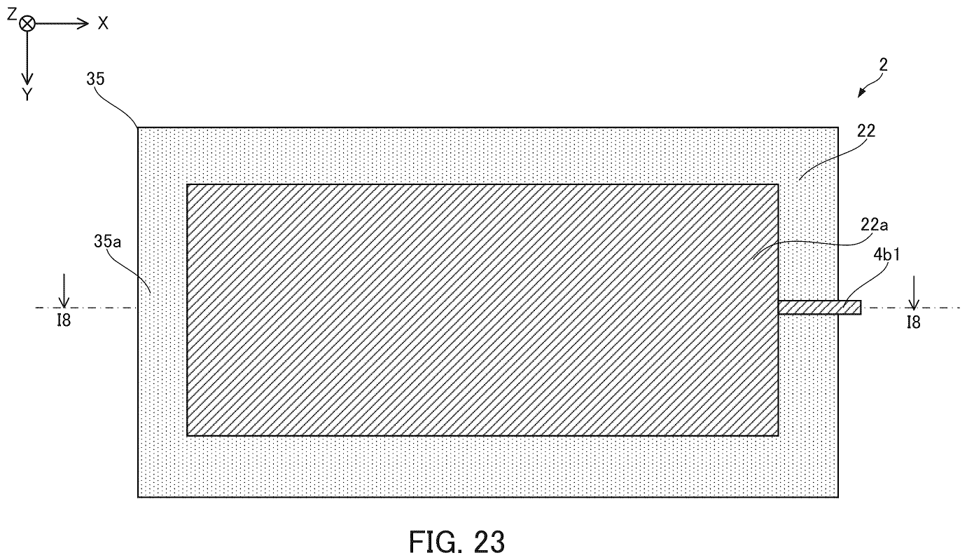

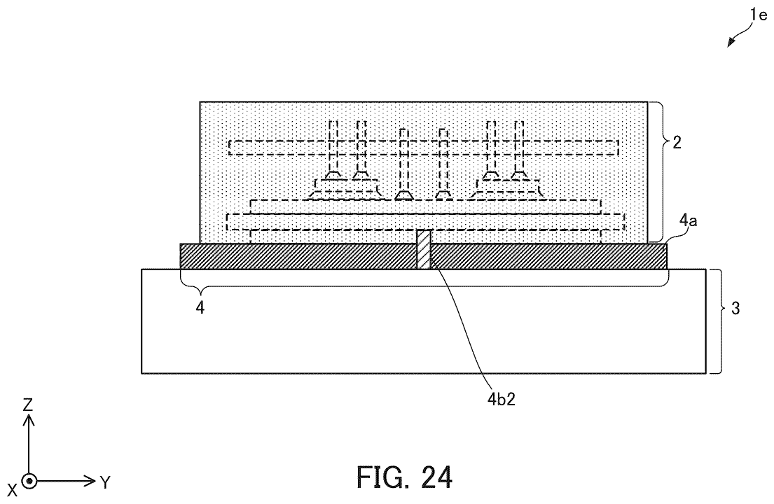

A semiconductor device 1e according to a sixth embodiment will now be described with reference to FIGS. 22 to 24. FIG. 22 is a side sectional view of a semiconductor device according to the sixth embodiment. FIG. 23 is a rear view of the semiconductor module according to the sixth embodiment. FIG. 24 is a side view of the semiconductor device according to the sixth embodiment. Note that FIG. 23 is a cross-sectional view of a semiconductor device 1e in FIG. 22 taken along the X-Y plane indicated by a chain line. That is, FIG. 23 is a plan view of the encapsulating lower surface 35a of the semiconductor module 2. FIG. 22 is a cross-sectional view taken along a chain I8-I8 in FIG. 23 when looking in the +Y direction. FIG. 24 is a side view of the semiconductor device 1e in FIG. 22 when looking in the −X direction.

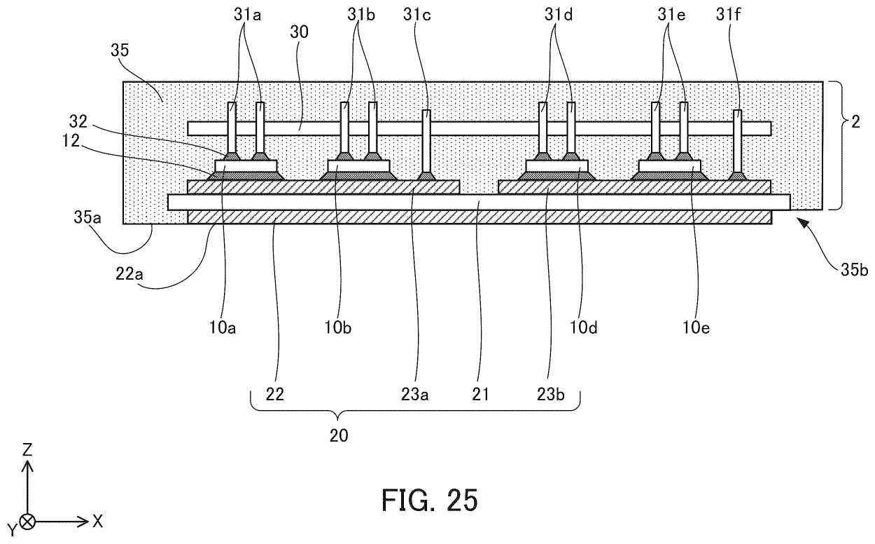

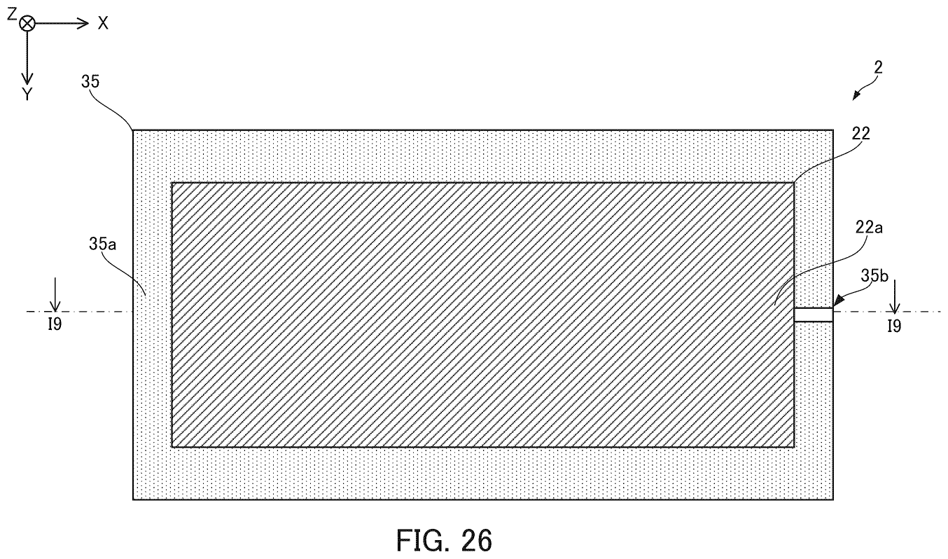

The semiconductor device 1e includes the semiconductor module 2, the cooling module 3, and the bonding member 4 that fixes the semiconductor module 2 and the cooling module 3. As in the first embodiment, the semiconductor module 2 includes the semiconductor chips 10a, 10b, 10d, and 10e, the insulated circuit board 20, the printed circuit board 30, and the encapsulating member 35 that encapsulates these components. However, a channel 35b (see FIGS. 25 and 26) is formed in the encapsulating lower surface 35a of the encapsulating member 35 included in the semiconductor module 2 of the semiconductor device 1e. The cooling module 3 is the same as in the first embodiment.

The bonding member 4 includes the thermally conductive part 4a and the electrically conductive part 4b. The thermally conductive part 4a is provided so as to include the entire heat dissipation surface 22a of the heat dissipation plate 22 included in the semiconductor module 2. That is, the thermally conductive part 4a may be formed in a wider shape than the heat dissipation surface 22a in plan view. Here, a configuration where the thermally conductive part 4a is provided on the entire surface of the encapsulating lower surface 35a of the encapsulating member 35 included in the semiconductor module 2 is depicted.

The electrically conductive part 4b connects the cooling surface 3a of the cooling module 3 and a side surface of the heat dissipation plate 22 by extending along a part of the thermally conductive part 4a that protrudes from the heat dissipation plate 22. As one example, the electrically conductive part 4b is L-shaped in a side view, and includes a first part 4b1 and a second part 4b2 which are both linear in shape. The first part 4b1 is provided in a region (space) constructed by the channel 35b in the encapsulating member 35 of the semiconductor module 2, the heat dissipation plate 22 of the insulated circuit board 20, and the thermally conductive part 4a, described later. One end (the inner end) of the first part 4b1 is connected to the side surface of the heat dissipation plate 22. The other end (the outer end) of the first part 4b1 extends outward (in the +X direction) from the side surface of the encapsulating member 35 (and the thermally conductive part 4a).

The second part 4b2 is provided on a side portion of the thermally conductive part 4a, described later. One end (the upper end) of the second part 4b2 is integrally connected to the outer end of the first part 4b1. The other end (the lower end) of the second part 4b2 extends in the −Z direction and is connected to the cooling surface 3a of the cooling module 3.

Next, a method of manufacturing this semiconductor device 1e will be described with reference to FIG. 3 described above. The semiconductor device 1e is also formed according to the flowchart depicted in FIG. 3 of the first embodiment. The explanation below will mainly focus on manufacturing processes that differ from the first embodiment.

After steps S1 and S2 described in FIG. 3, an application process that applies the bonding member 4 is performed (step S3). This application process will be described with reference to FIGS. 25 and 26. FIGS. 25 and 26 are diagrams useful in explaining the application process in the sixth embodiment. Note that FIG. 26 is a rear view of the semiconductor module 2 in FIG. 25. FIG. 25 is a cross-sectional view taken along a chain line I9-I9 in FIG. 26, when looking in the +Y direction.

As depicted in FIGS. 25 and 26, the channel 35b, which extends perpendicularly outward from one short side of the heat dissipation surface 22a, may be formed for example by cutting an end portion on one short side of the encapsulating lower surface 35a in plan view of the semiconductor module 2 formed in step S2. It is sufficient for the channel 35b to extend from the side surface of the encapsulating member 35 to the side surface of the heat dissipation surface 22a, and the number of the channels 35b and their formation positions may be freely chosen. It is also sufficient for the width (in the ±Y direction or the ±X direction) of the channels 35b to be a predetermined length.

Note that the channel 35b is not limited to being formed in the semiconductor module 2 in step S3. As another example, during the encapsulating in step S2c, the channel 35b may be introduced by encapsulating the semiconductor module 2 with the encapsulating member 35 while leaving any positions where the channel 35b is to be formed empty.

Next, the first part 4b1 of the electrically conductive part 4b is applied to the channel 35b of the encapsulating lower surface 35a of the semiconductor module 2. The material applied here may be electrically conductive adhesive, for example. The outer end of the first part 4b1 of the applied electrically conductive part 4b is exposed from the side surface of the encapsulating member 35.

The thermally conductive part 4a is then applied to the cooling surface 3a of the cooling module 3 in the region in which the encapsulating lower surface 35a is disposed. Alternatively, the thermally conductive part 4a may be applied to the entire surface of the encapsulating lower surface 35a including the first part 4b1 of the electrically conductive part 4b of the semiconductor module 2.

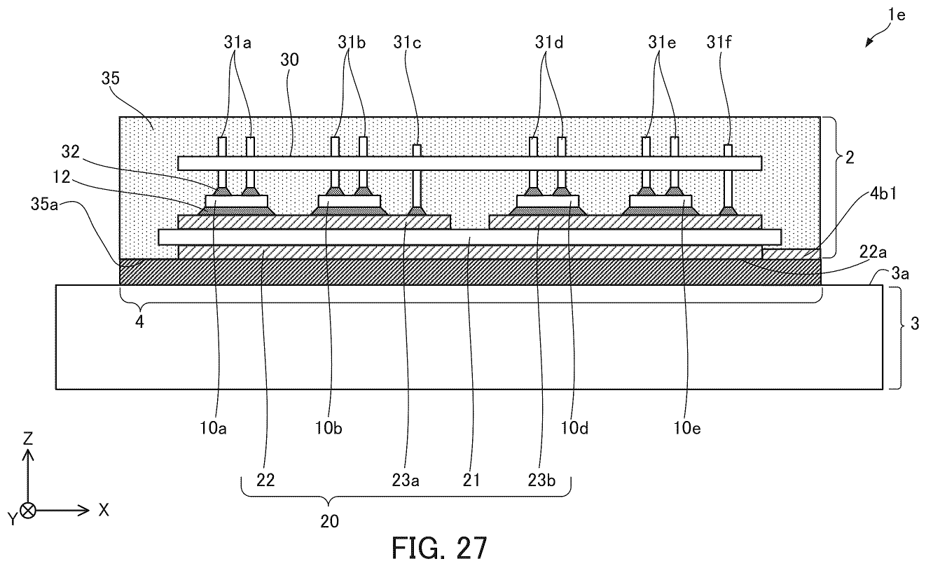

Next, an attachment process that attaches the heat dissipation surface 22a of the heat dissipation plate 22 of the semiconductor module 2 via the thermally conductive part 4a of the bonding member 4 to the cooling surface 3a of the cooling module 3 is performed (step S4). This attachment process will be described with reference to FIG. 27. FIG. 27 is a diagram useful in explaining an attachment process according to the sixth embodiment. This attachment process is performed in the same way as in the first embodiment, and as depicted in FIG. 27, the thermally conductive part 4a is provided between the encapsulating lower surface 35a including the first part 4b1 of the electrically conductive part 4b of the semiconductor module 2 and the cooling surface 3a of the cooling module 3.

The second part 4b2 of the electrically conductive part 4b is formed on the cooling surface 3a of the cooling module 3 along the side portion of the thermally conductive part 4a from the outer end of the first part 4b1 of the electrically conductive part 4b exposed from the side surface of the encapsulating member 35 of the semiconductor module 2. As one example, the conductive adhesive may be applied as the second part 4b2 from the outer end of the first part 4b1 of the electrically conductive part 4b exposed from the side surface of the encapsulating member 35 of the semiconductor module 2 along the side portion of the thermally conductive part 4a to the cooling surface 3a of the cooling module 3. Through the processes described above, the semiconductor device 1e depicted in FIGS. 22 to 24 is obtained.

In the sixth embodiment also, the bonding member 4 includes the thermally conductive part 4a, which bonds the heat dissipation surface 22a and the cooling surface 3a, and the electrically conductive part 4b, which directly connects the heat dissipation plate 22 and the cooling surface 3a. This makes it possible to set the heat dissipation plate 22 and the cooling module 3 at the same potential, which prevents the occurrence of corona discharge. The semiconductor device according to the sixth embodiment is electrically stable, which prevents any drop in reliability.

According to the technology disclosed here, a semiconductor device is electrically stabilized.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a heat dissipation plate having a heat dissipation surface;
a cooling module having a cooling surface, the cooling module being disposed so that the cooling surface faces the heat dissipation surface of the heat dissipation plate; and
a bonding member provided between the heat dissipation surface and the cooling surface;
wherein the bonding member includes:
a thermally conductive part that bonds the heat dissipation surface and the cooling surface, and
an electrically conductive part that directly connects the heat dissipation plate to the cooling surface.

2. The semiconductor device according to claim 1,
wherein the thermally conductive part of the bonding member adheres to the heat dissipation surface and the cooling surface, and is electrically insulating.

3. The semiconductor device according to claim 2,
wherein the thermally conductive part of the bonding member has epoxy resin as a main component thereof.

4. The semiconductor device according to claim 3,
wherein a main component of the electrically conductive part of the bonding member is the same as the main component of the thermally conductive part, and contains an electrically conductive filler.

5. The semiconductor device according to claim 4,
wherein the filler has one of silver, copper, gold, nickel, chromium, aluminum, and an alloy containing at least one of silver, copper, gold, nickel, chromium, and aluminum as a main component thereof.

6. The semiconductor device according to claim 1,
wherein the electrically conductive part of the bonding member has a conductive member as a main component thereof.

7. The semiconductor device according to claim 6,
wherein the electrically conductive member is any one of solder, a paste of metal particles, and a conductive adhesive.

8. The semiconductor device according to claim 7,
wherein the paste of metal particles includes metal particles of silver, copper, or an alloy containing silver and/or copper.

9. The semiconductor device according to claim 1,
wherein the bonding member has a shape that corresponds to the heat dissipation surface of the heat dissipation plate in a plan view of the semiconductor device.

10. The semiconductor device according to claim 9,
wherein the electrically conductive part of the bonding member is formed along an outer edge of the heat dissipation surface of the heat dissipation plate in the plan view.

11. The semiconductor device according to claim 10,
wherein the electrically conductive part of the bonding member is formed in a continuous annular shape along the outer edge of the heat dissipation surface of the heat dissipation plate in the plan view.

12. The semiconductor device according to claim 10,
wherein the heat dissipation surface of the heat dissipation plate has a rectangular shape in the plan view, and
the electrically conductive part of the bonding member is formed along a side at an outer edge of the heat dissipation surface of the heat dissipation plate in the plan view.

13. The semiconductor device according to claim 10,
wherein the thermally conductive part and the electrically conductive part of the bonding member are mutually exclusive in the plan view.

14. The semiconductor device according to claim 10,
wherein the thermally conductive part and the electrically conductive part of the bonding member are in contact with each other.

15. The semiconductor device according to claim 10,
wherein the thermally conductive part and the electrically conductive part of the bonding member are formed with a gap therebetween.

16. The semiconductor device according to claim 1, further comprising an encapsulating member that encapsulates the heat dissipation plate and exposes the heat dissipation surface from an encapsulating lower surface thereof,
wherein the bonding member is wider than the heat dissipation surface of the heat dissipation plate in a plan view of the semiconductor device.

17. The semiconductor device according to claim 16,
wherein the electrically conductive part of the bonding member overlaps the heat dissipation surface of the heat dissipation plate in the plan view.

18. The semiconductor device according to claim 1, wherein
the thermally conductive part of the bonding member is wider than the heat dissipating surface in a plan view of the semiconductor device, and has a protruding part that protrudes from the heat dissipation plate, and
the electrically conductive part of the bonding member connects the cooling surface and a side surface of the heat dissipation plate along the protruding part of the thermally conductive part.
